(19) United States
(12) Patent Application Publication
(10) Pub. No.: US 2006/0283702 A1
(43) Pub. Date: Dec. 21, 2006

(54) Random pulsed DC power supply

(75) Inventor: Akihiro Hosokawa, Cupertino, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/158,116

(22) Filed: Jun. 21, 2005

(51) Int. Cl. C23C 14/32; C23C 14/00

(52) U.S. Cl. 204/192.1; 204/298.08

(57) ABSTRACT

A power supply for use in a physical vapor deposition chamber having a target and a substrate support, comprising a power source configured to bias the target with a sputtering voltage relative to the substrate support and configured to bias the target with a reverse voltage about 10 or more times for a period of about one second after an arc is detected inside the physical vapor deposition chamber

### BACKGROUND OF THE INVENTION

1. Field of the Invention

Embodiments of the present invention generally relate to substrate processing systems, such as physical vapor deposition systems.

2. Description of the Related Art

Physical vapor deposition (PVD) is one of the most commonly used processes in fabrication of electronic devices, such as flat panel displays. PVD is a plasma process performed in a vacuum chamber where a negatively biased target is exposed to a plasma of an inert gas having relatively heavy atoms (e.g., argon) or a gas mixture comprising such inert gas. Bombardment of the target by ions of the inert gas results in ejection of atoms of the target material. The ejected atoms accumulate as a deposited film on a substrate placed on a substrate pedestal disposed underneath the target within the chamber. Flat panel sputtering is principally distinguished from the long developed technology of wafer sputtering by the large size of the substrates and their rectangular shape.

Arcing sometimes occur inside the chamber during sputtering. The arcing may be caused by one or more particles or contaminants attached to the target. In addition, the target may contain some impurities, which may cause splashing. That is, positive charges on the particles may be attracted to negative charges on the impurities, thereby causing the particles to melt into the target and create an electrical short, i.e., a splash. These arcing and splashing may in turn cause non-uniformities on the film deposited on the substrate.

Therefore, a need exists in the art for a method for removing the particles from the target, thereby stopping arcing or splashing from occurring inside the chamber.

### SUMMARY OF THE INVENTION

Embodiments of the invention are directed to a method for biasing a target in a physical vapor deposition chamber. The method includes biasing the target with a voltage to generate a plasma inside the chamber and reversing the voltage about 10 or more times for a period of about one second after an arc is detected inside the physical vapor deposition chamber.

In one embodiment, each reverse voltage lasts for about 1 millisecond to about 10 milliseconds.

Embodiments of the invention are also directed to a power supply for use in a physical vapor deposition chamber having a target and a substrate support, comprising a power source configured to bias the target with a sputtering voltage relative to the substrate support and configured to bias the target with a reverse voltage about 10 or more times for a period of about one second after an arc is detected inside the physical vapor deposition chamber.

Embodiments of the invention are also directed to a physical vapor deposition chamber, which includes a target, a substrate support for holding a substrate and a power source configured to bias the target with a sputtering voltage relative to the substrate support. The power source is configured to bias the target with a reverse voltage about 10 or more times for a period of about one second after an arc is detected inside the physical vapor deposition chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process chamber that may be used in connection with one or more embodiments of the invention.

FIG. 2 illustrates a flow diagram of a method for biasing the target in accordance with one or more embodiments of the invention.

FIG. 3 illustrates a voltage diagram of a power supply in accordance with one or more embodiments of the invention.

### DETAILED DESCRIPTION

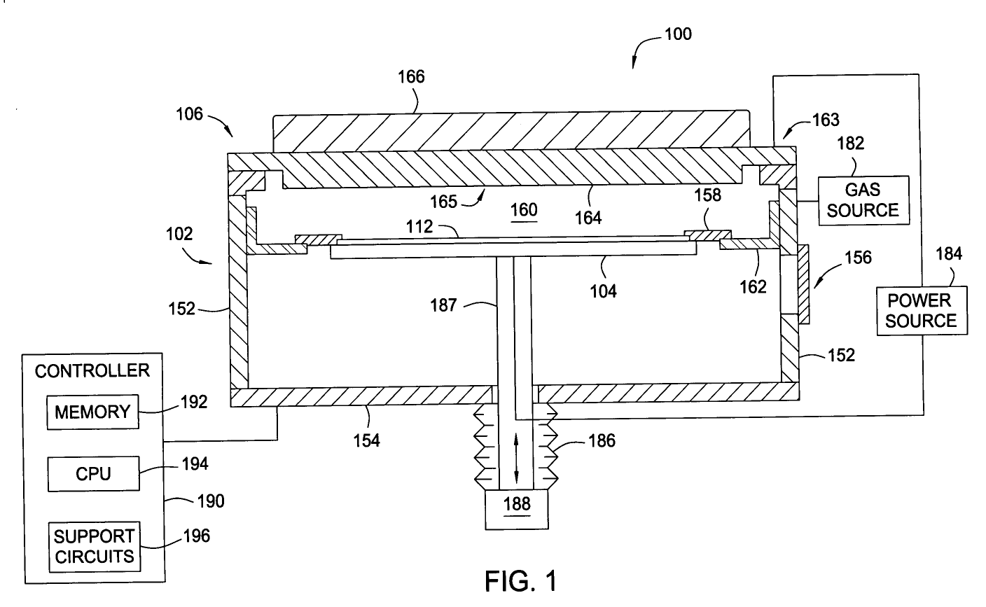

FIG. 1 illustrates a process chamber 100 that may be used in connection with one or more embodiments of the invention. One example of a process chamber 100 that may be adapted to benefit from the embodiments of the invention is a PVD process chamber, available from AKT, Inc., located in Santa Clara, Calif.

The process chamber 100 includes a chamber body 102 and a lid assembly 106 that define an evacuable process volume 160. The chamber body 102 is typically fabricated from welded stainless steel plates or a unitary block of aluminum. The chamber body 102 generally includes sidewalls 152 and a bottom 154. The sidewalls 152 and/or bottom 154 may include a plurality of apertures, such as an access port 156, a shutter disk port (not shown) and a pumping port (not shown). The access port 156 provides for entrance and egress of a substrate 112 to and from the process chamber 100. The pumping port is typically coupled to a pumping system that evacuates and controls the pressure within the process volume 160.

A substrate support 104 is disposed inside the chamber body 102 and is configured to support the substrate 112 thereupon during processing. The substrate support 104 may be fabricated from aluminum, stainless steel, ceramic or combinations thereof. A shaft 187 extends through the bottom 154 of the chamber 102 and couples the substrate support 104 to a lift mechanism 188. The lift mechanism 188 is configured to move the substrate support 104 between a lower position and an upper position. A bellows 186 is typically disposed between the lift mechanism 188 and the chamber bottom 154 and provides a flexible seal therebetween, thereby maintaining vacuum integrity of the process volume 160.

Optionally, a bracket 162 and a shadow frame 158 may be disposed within the chamber body 102. The bracket 162 may be coupled to the sidewall 152 of the chamber body 102. The shadow frame 158 is generally configured to confine deposition to a portion of the substrate 112 exposed through the center of the shadow frame 158. When the substrate support 104 is moved to the upper position for processing, an outer edge of the substrate 112 disposed on the substrate support 104 engages the shadow frame 158 and lifts the shadow frame 158 from the bracket 162. Alternatively, shadow frames having other configurations may optionally be utilized as well.

The substrate support 104 may be moved into a lower position for loading and unloading the substrate 112 from the substrate support 104. In the lower position, the substrate support 104 is positioned below the bracket 162 and the access port 156. The substrate 112 may then be removed from or placed into the chamber 100 through the access port 156. Lift pins (not shown) may be selectively moved through the substrate support 104 to space the substrate 112 away from the substrate support 104 to facilitate the placement or removal of the substrate 112 by a wafer transfer mechanism disposed exterior to the process chamber 100.

The lid assembly 106 generally includes a target 164, which is configured to provide material that is deposited on the substrate 112 during the PVD process. The target 164 may include a peripheral portion 163 and a central portion 165. The peripheral portion 163 is typically disposed over the sidewalls 152. The central portion 165 of the target 164 may protrude, or extend in a direction, towards the substrate support 104. It is contemplated that other target configurations may be utilized as well. For example, the target 164 may include a backing plate having a central portion of a desired material bonded or attached thereto. The target material may also include adjacent tiles or segments of material that together form the target 164. In one embodiment, the target 164 may be made from a metallic material, such as aluminum, molybdenum, titanium or chromium.

In this embodiment, the target 164 operates as a cathode and the substrate support 104 operates as an anode. Other embodiments contemplate other components of the process chamber 100 to operate as the cathode and the anode. The target 164 and substrate support 104 may be biased relative to each other by a power source 184, such as a DC power source. Other embodiments, however, contemplate other types of power sources commonly known by persons of ordinary skill in the art. The power source 184 may include an arc detection mechanism commonly known by persons of ordinary skill in the art. Arcing may be detected by a significant drop in voltage or a significant increase in voltage. Such arcing detection may commonly be referred to as micro arcing detection. The power source 184 may also include or be in communication with a switch, oscillators and other circuits for reversing the voltage applied to the target as commonly known by persons of ordinary skill in the art.

The power source 184 may be configured to cause deposition of a coating material on the substrate 112 by creating an electric potential across the target 164 and the substrate support 104, thereby forming a plasma between the substrate 112 and the target 164. Ions within the plasma are accelerated toward the target 164 and cause material to become dislodged from the target 164. The dislodged material is attracted towards the substrate 112 and deposits a film of material thereon. The lid assembly 106 may further include a magnetron 166 to enhance consumption of the target material during deposition. A gas, such as argon, may be supplied to the process volume 160 from a gas source 182 through one or more apertures (not shown), which may be formed in the sidewalls 152 of the process chamber 100.

The process chamber 100 may be in communication with a controller 190, which typically includes a central processing unit (CPU) 194, support circuits 196 and memory 192. The CPU 194 may be one of any form of computer processor that can be used in an industrial setting for controlling various chambers and sub-processors. The memory 192 is coupled to the CPU 194. The memory 192 may be a computer-readable medium or one or more of readily available memory, such as random access memory (RAM), read only memory (ROM), floppy disk, hard disk, or any other form of digital storage, local or remote. The support circuits 196 are coupled to the CPU 194 for supporting the CPU 194 in a conventional manner. These circuits 196 may include cache, power supplies, clock circuits, input/output circuitry, subsystems, and the like. The controller 190 may be used to control operation of the process chamber 100, including any deposition processes performed therein.

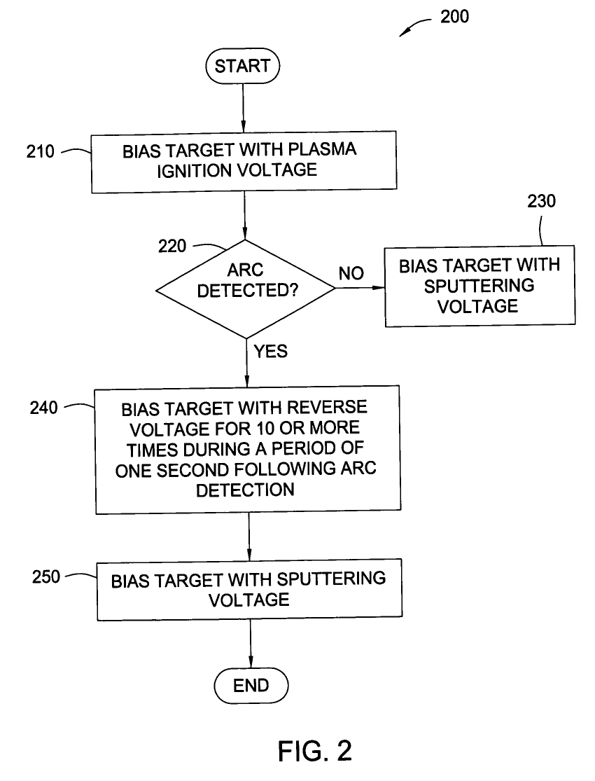

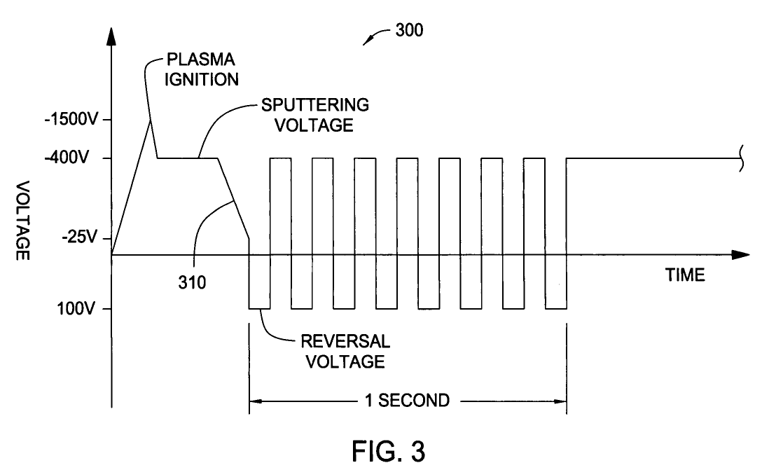

FIG. 2 illustrates a flow diagram of a method 200 for biasing the target 164 in accordance with one or more embodiments of the invention. At step 210, the target 164 is biased with a voltage of about −800 volts during plasma ignition. This voltage eventually stabilizes to a sputtering voltage, which is typically about −500 volts. Although embodiments of the invention are described with reference to −800 volts plasma ignition voltage and −500 volts sputtering voltage, other embodiments contemplate other amounts commonly known by persons of ordinary skill in the art. For instance, the plasma ignition voltage illustrated in FIG. 3 is about −1500 volts and the sputtering voltage is about −400 volts. At step 220, a determination is made as to whether an arc has been detected inside the chamber 100. The arc may be detected by arc detection methods commonly known by persons of ordinary skill in the art. If no arc has been detected, then the target 164 is continued to be biased with the sputtering voltage (step 230).

If an arc has been detected, then the voltage biasing the target 164 is reversed to a polarity opposite the sputtering voltage about 10 or more times for a period of about one second following the arc detection (step 240). In one embodiment, the target 164 may be biased with a reverse voltage having a polarity opposite of the sputtering voltage. The magnitude of the reverse voltage may range from about 25 volts to about 125 volts. As an example, the reverse voltage may have a magnitude of about 100 volts. The magnitude of the reverse voltage may be about 5% to about 25% of the sputtering voltage. In one embodiment, the reversal of voltage may occur about every 5 milliseconds to about every 10 milliseconds during that one second period. Such embodiment may be employed during hard arcing conditions. In another embodiment, each reversal may last from about 1 millisecond to about 10 milliseconds. For example, if the voltage is reversed for about 10 times during that one second period, then each reversal may last for about 10 milliseconds. As another example, if the voltage is reversed for about 20 times during that one second period, then each reversal may last for about 5 milliseconds. In yet another embodiment, each reversal may last from about 5 microseconds to about 10 microseconds during micro arcing conditions. In this manner, biasing the target with a reverse voltage about 10 or more times for a period of about one second following the arc detection is configured to remove the particles that caused the arc and stop the arc from occurring. Various embodiments of the invention may also be applied to stop splashing from occurring on the target 164.

One advantage of biasing the target with a reverse voltage about 10 or more times for a period of about one second following the arc detection is the assurance that the particles that caused the arcing have been removed from the target. In contrast, the prior art proposes either biasing target with a reverse voltage once following an arc detection, which may not be sufficient to remove the particles from the target, or continuously biasing the target with a reverse voltage, which is overkill.

Once arcing has stopped, the target 164 is biased with the sputtering voltage (step 250). Although embodiments of the invention are described with reference to negative plasma ignition voltage and negative sputtering voltage, other embodiments contemplate the use of positive plasma ignition voltage and positive sputtering voltage.

FIG. 3 illustrates a voltage diagram 300 of the power source 184 in accordance with one or more embodiments of the invention. The voltage diagram 300 has voltage as the y axis and time as the x axis. Plasma is ignited at a voltage of about −1500 volts, which eventually stabilizes to a sputtering voltage, which is about −400 volts. Arcing causes the voltage to drop to about −25 volts, at which point the voltage is reversed for 10 times during a one second period following the arc detection. The reversal voltage is about 100 volts.

In one embodiment, the number of times the voltage may be reversed may be determined by the rate of change in voltage drop due to the arc. The rate of change in voltage drop is illustrated as slope 310 in FIG. 3. For example, if the rate of change in voltage drop due to the arc is about 25 volts per microsecond, then the voltage is reversed for about 10 times. If the rate of change in voltage drop due to the arc is about 50 volts per microsecond, then the voltage is reversed for about 20 times. If the rate of change in voltage drop due to the arc is about 100 volts per microsecond, then the voltage is reversed for about 40 times. In this manner, the steeper the slope, the more frequently the voltage is reversed.

While the foregoing is directed to embodiments of the present invention, other and further embodiments of the invention may be devised without departing from the basic scope thereof, and the scope thereof is determined by the claims that follow.

What is claimed is:

1. A method for biasing a target in a physical vapor deposition chamber, comprising:
biasing the target with a voltage to generate a plasma inside the chamber; and
reversing the voltage about 10 or more times for a period of about one second after an arc is detected inside the physical vapor deposition chamber.

2. The method of claim 1, wherein reversing the voltage comprises reversing the voltage about 10 times to about 20 times.

3. The method of claim 1, wherein reversing the voltage comprises reversing the voltage from about every 5 milliseconds to about every 10 milliseconds.

4. The method of claim 1, wherein reversing the voltage comprises reversing the voltage for about 1 millisecond to about 10 milliseconds each time.

5. The method of claim 1, wherein reversing the voltage comprises reversing the voltage for about 5 microseconds to about 10 microseconds each time.

6. The method of claim 1, wherein reversing the voltage comprises reversing the voltage about 10 times for about 10 milliseconds each time.

7. The method of claim 1, wherein reversing the voltage comprises reversing the voltage about 20 times for about 5 milliseconds each time.

8. The method of claim 1, wherein reversing the voltage comprises reversing the voltage about 10 times if the voltage drop rate of change due to the arc is about 25 volts per microsecond.

9. The method of claim 1, wherein reversing the voltage comprises reversing the voltage about 20 times if the voltage drop rate of change due to the arc is about 50 volts per microsecond.

10. The method of claim 1, wherein reversing the voltage comprises reversing the voltage about 40 times if the voltage drop rate of change due to the arc is about 100 volts per microsecond.

11. The method of claim 1, wherein reversing the voltage comprises reversing the voltage at a magnitude of about 100 volts.

12. The method of claim 1, wherein reversing the voltage comprises reversing the voltage at a magnitude from about 25 volts to about 125 volts.

13. The method of claim 1, wherein the voltage is reversed to remove one or more particles that cause the arc from the target.

14. The method of claim 1, wherein the voltage is reversed to stop the arc from occurring.

15. A method for biasing a target in a physical vapor deposition chamber, comprising:
biasing the target with a sputtering voltage to generate a plasma inside the chamber; and
biasing the target with a reverse voltage about 10 or more times for a period of about one second after an arc is detected inside the physical vapor deposition chamber, wherein each reverse voltage lasts for about 1 millisecond to about 10 milliseconds.

16. The method of claim 15, wherein the reverse voltage is about 5% to about 25% the sputtering voltage.

17. The method of claim 15, wherein biasing the target with the reverse voltage comprises biasing the target with the reverse voltage about 10 times if the voltage drop rate of change due to the arc is about 25 volts per microsecond.

18. The method of claim 15, wherein biasing the target with the reverse voltage comprises biasing the target with the reverse voltage about 20 times if the voltage drop rate of change due to the arc is about 50 volts per microsecond.

19. The method of claim 15, wherein biasing the target with the reverse voltage comprises biasing the target with the reverse voltage about 40 times if the voltage drop rate of change due to the arc is about 100 volts per microsecond.

20. A power supply for use in a physical vapor deposition chamber having a target and a substrate support, comprising a power source configured to bias the target with a sputtering voltage relative to the substrate support and configured to bias the target with a reverse voltage about 10 or more times for a period of about one second after an arc is detected inside the physical vapor deposition chamber.

21. The power supply of claim 20, wherein each reverse voltage lasts for about 1 millisecond to about 10 milliseconds.

22. The power supply of claim 20, wherein the reverse voltage is about 5% to about 25% the sputtering voltage.

23. A physical vapor deposition chamber, comprising:
a target;
a substrate support for holding a substrate; and
a power source configured to bias the target with a sputtering voltage relative to the substrate support, wherein the power source is configured to bias the target with a reverse voltage about 10 or more times for a period of about one second after an arc is detected inside the physical vapor deposition chamber.

24. The physical vapor deposition chamber of claim 23, wherein each reverse voltage lasts for about 1 millisecond to about 10 milliseconds.

25. The physical vapor deposition chamber of claim 23, wherein the reverse voltage is about 5% to about 25% the sputtering voltage.
